(19) United States
(12) Patent Application Publication
(10) Pub. No.: US 2007/0221910 A1
(43) Pub. Date: Sep. 27, 2007

(54) Intermediate Layer in Electroluminescent Arrangements and Electroluminescent Arrrangement

(75) Inventors: Hans-Helmut Bechtel, Roetgen (DE); Wolfgang Busselt, Roetgen (DE); Joachim Opitz, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONIC, N.V., EINDHOVEN (NL)

(21) Appl. No.: 10/599,387

(22) PCT Filed: Mar. 22, 2005
(86) PCT No.: PCT/IB05/50978

§ 371 Date: Sep. 27, 2006

(30) Foreign Application Priority Data
Mar. 31, 2004 (EP) 04101310.3

(51) Int. Cl. H01L 51/30; H01L 29/12

(52) U.S. Cl. 257/40; 257/103; 257/79; 257/E29.068; 257/E51.024

(57) ABSTRACT

An intermediate layer (11) comprises a basic material such as a conductive polymer that taken alone still absorbs some light. Combined with colloidal particles (12) the intermediate layer (11) becomes almost fully transparent. An electroluminescent arrangement with an intermediate layer (11) that is almost fully transparent because of colloidal particle (12) comprised therein has an increased efficiency and thus requires less energy for the same luminescent properties.

The invention relates to an intermediate layer in an electroluminescent (EL) arrangement. The intermediate layer may be either a hole (a positive charge) injection and/or a hole transportation layer or an electron (a negative charge) injection and/or an electron transportation layer which is arranged between two electrodes together with a light emitting layer. When a voltage is applied across the two electrodes the EL arrangement emits light because of the current flow.

The EL arrangement may consist of anorganic semiconductor materials or organic materials (Organic Light Emitting Diodes OLED).

LEDs, which comprise at least one layer consisting of a polymer therefore are called PolyLEDs or PLEDs. A common polymer used for PolyLEDs is Poly(ethylene dioxythiophene) (PEDT or PDOT) which is a material that is highly absorbing for visible light. Thus, even a PolyLED layer that is extremely thin still absorbs about 5 to 10 percent of the emitted light.

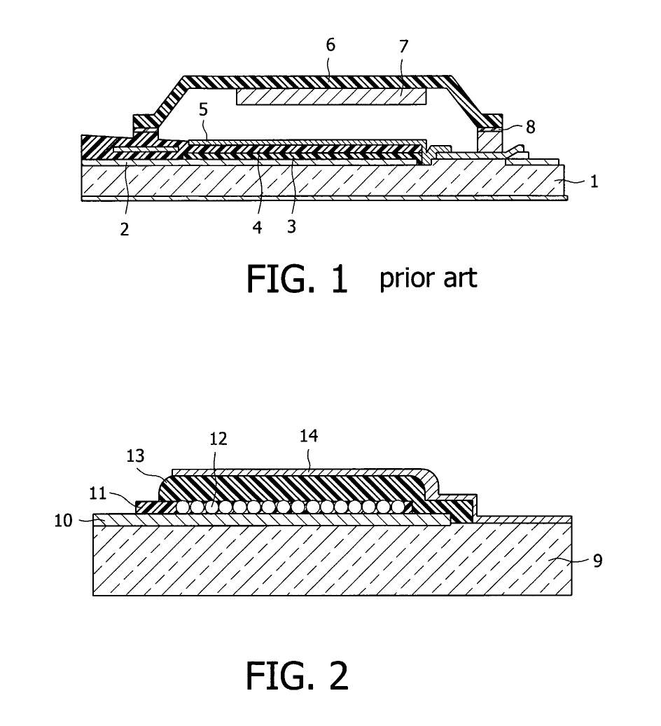

PolyLEDs are used for displays for monochrome or full color RGB (Red/Green/Blue) PolyLED devices. A schematic structure of a PolyLED display is shown in FIG. 1 concerning the prior art. A glass panel 1, which forms the front side of the display has a structured Indium-Tin-Oxide (ITO) electrode 2. Two organic layers 3, 4 are deposited onto the ITO electrode 2 by spin coating or ink jetting for example. The first organic layer 3, which is deposited onto the ITO electrode 2 consists of a conductive Polymer which is used for the transport and the injection of positive charge carriers or holes. The second layer 4 consists of a Polymer, which is emitting light when a voltage is applied. It is custom to use a mixture of PDOT and PSS poly (styrene sulphonate) in order to achieve a high efficiency and a good live span. As a third layer 5 a cathode metal is deposited onto the emissive layer 4. A cover lid 6 comprising a getter 7 is adhered to the structure by glue 8.

An object of the invention is to provide an intermediate layer for an electroluminescent arrangement which comprises at least one hole (a positive charge) or electron (a negative charge) transportation and/or injection layer together with at least one light emitting layer arranged between an anode electrode and a cathode electrode with the electroluminescent arrangement emitting light when a voltage is applied across the two electrodes and with the intermediate layer absorbing less light of the visible spectral range.

A further object of the invention is to provide an electroluminescent arrangement with an increased efficiency due to reduced absorption of light of the visible spectral range with less energy used for the same luminescence.

As regards the intermediate layer the object is solved by a transportation and/or injection layer that comprises colloidal particles with particle diameters in the range of 10⁻⁷ to 10⁻⁴ cm, which are transparent for light of the visible spectral range. The colloidal particles may be either an organic material such as postchlorinated polyvinyl chloride (PC) or latex or an anorganic material such as an oxide, a phosphate, a silicate or a borate. They just have to be compatible with the production conditions, e.g. the process temperature during the production of PLEDs rises up to 200° C.

It is advantageous that the colloidal particles' index of refraction is in the range of the basic material's index of refraction as thus the contrast at daylight is highest.

The colloidal particles of the intermediate layer may be colloidal silicon dioxide particles. The results of measurements have shown that the percentage of the light emitting from the layer structure increases when the basic material further comprises silicon dioxide particles.

As regards the electroluminescent arrangement the object is solved by an EL arrangement with an intermediate layer, which comprises a basic material and furthermore colloidal particles as well as either
an anode electrode that transmits light of the visible spectral range and a cathode electrode that reflects light of the visible spectral range or
a cathode electrode that transmits light of the visible spectral range and an anode electrode that reflects light of the visible spectral range or
both the cathode and the anode transmit visible light.

The presence of colloidal particles results in an enhanced outcoupling of the light. That is why the voltage applied across the two electrodes can be lower while the EL arrangement has the same luminescence compared to the prior art.

According to one embodiment of the electroluminescent arrangement the cathode electrode transmits light as it is transparent and comprises a thin and thus as well transparent silver layer onto which one or more further transparent dielectric layers are deposited. This arrangement is preferably used for active matrix displays with independently activated pixels where additionally transistors are selected.

According to a preferred embodiment of the electroluminescent arrangement the average diameter of the colloid particles is smaller than twice the size of the transportation layer's thickness as under this condition the electrical properties of the device almost do not change.

According to one embodiment the electroluminescent arrangement comprises a transportation layer with colloidal particles that preferably transports holes and is made of PDOT or TPD (Triphenyldiamine derivatives).

According to a further embodiment the electroluminescent arrangement comprises a transportation layer with colloidal particles that preferably transports electrons.

The electroluminescent arrangement's light emitting layer may be a polymer such as poly(p-phenylene venylene) (PPV) and/or a solution processed organic material.

The electroluminescent arrangement's light emitting layer may be made of a vacuum deposited organic material such as Tris(8-quinolinol)aluminium (Alq₃).

According to a preferred embodiment the charge transportation layer consists of PDOT, which comprises 5 times the amount (weight) of silicon dioxide (SiO₂) particles with a size (diameter) of 120 nm.

The electroluminescent arrangement may be used as an active matrix display, a passive matrix display or a light source either for monochrome or for full color application.

In the following, the invention will be described in further detail with reference to the accompanying drawing, wherein

FIG. 2 shows a sectional view of a schematic display with colloidal particles whose average diameter corresponds to the charge transportation layer's thickness;

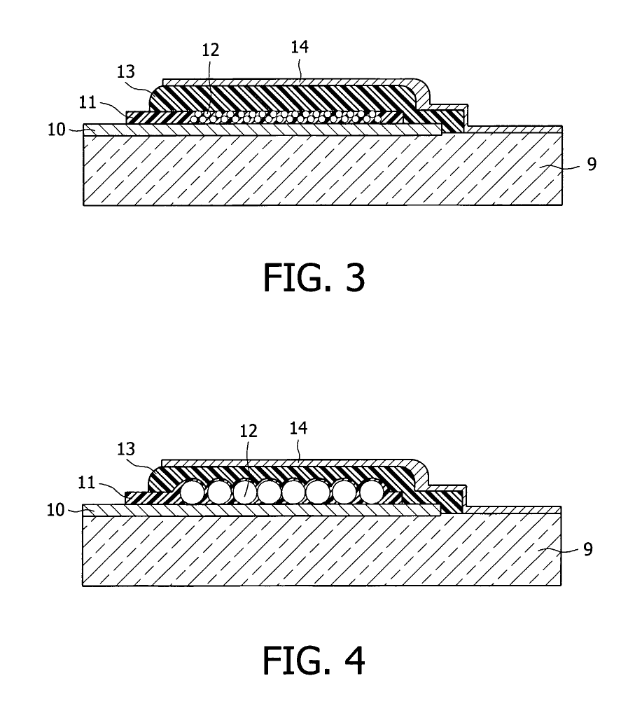

FIG. 3 shows the sectional view of FIG. 2 with colloidal particles whose average diameter corresponds to half of the size of the charge transportation layer's thickness;

FIG. 4 shows the sectional view of FIG. 2 with colloidal particles whose average diameter corresponds to twice the size of the charge transportation layer's thickness.

FIG. 2 shows a sectional view of a schematic display with colloidal particles 12 whose average diameter corresponds to the charge transportation layer's 11 thickness. Transportation layer 11 may either transport positive or negative charges and is deposited on an electrode, which is an ITO anode 10 in this example. Deposited onto the transportation layer 11 is an emissive layer 13 which also covers a projecting edge of the anode 10. In this example the bulk is covered with an cathode electrode 14 which covers most of the emissive layer 13 and part of a glass panel 9. The glass panel may be substituted by a flexible transparent material such as used for e-paper where the glass particles are deposited onto a transparent plastic material. This example concerns an LED an anode 10, which transmits visible light and a cathode 14 which reflects visible light.

FIG. 3 shows the sectional view of FIG. 2 with colloidal particles 12 whose average diameter corresponds to half of the size of the charge transportation layer's 11 thickness.

FIG. 4 shows the sectional view of FIG. 2 with colloidal particles 12 whose average diameter corresponds to twice the size of the charge transportation layer's 11 thickness. This is the maximum because up to this size the influence on the electrical behavior of the LED is almost negligible.

The invention may be summarized with an intermediate layer that comprises a basic material, such as a conductive polymer, that taken alone still absorbs some light. Combined with colloidal particles the intermediate layer becomes almost fully transparent. An electroluminescent arrangement with an intermediate layer that is almost fully transparent because of colloidal particles comprised therein has an increased efficiency and thus requires less energy for the same luminescent properties.

1. An intermediate layer for an electroluminescent arrangement which comprises at least one light emitting layer (13) and at least one hole (a positive charge) or electron (a negative charge) transportation and/or injection layer (11) of a basic material arranged between an anode electrode (10) and a cathode electrode (11) with the electroluminescent arrangement emitting light when a voltage is applied across the two electrodes (10, 13), characterized in that the transportation and/or injection layer (11) further comprises colloidal particles (12).

2. An intermediate layer according to claim 1, characterized in that the colloidal particles (12) are an organic material especially an organic material selected from the group consisting of PC or latex.

3. An intermediate layer according to claim 1, characterized in that the colloidal particles (12) are an anorganic material, especially an anorganic material selected from the group consisting of an oxide, a phosphate, a silicate or a borate.

4. An intermediate layer according to claim 1, characterized in that the colloidal particles' (12) index of refraction is in the range of the basic material's index of refraction.

5. An electroluminescent arrangement with an intermediate layer according to claim 1, characterized in that—the anode electrode (10) transmits light of the visible spectral range and the cathode (14) electrode reflects light of the visible spectral range or—the cathode electrode (14) transmits light of the visible spectral range and the anode electrode (10) reflects light of the visible spectral range or—both the cathode (14) and the anode (10) transmit visible light.

6. An electroluminescent arrangement according to claim 5, characterized in that the cathode electrode (14) transmits light and comprises a thin silver layer onto which one or more further transparent dielectric layers are deposited.

7. An electroluminescent arrangement according to claim 5, characterized in that the average diameter of the colloid particles (12) is smaller than twice the size of the transportation layer's (11) thickness.

8. An electroluminescent arrangement according to claim 5, characterized in that the transportation layer (11) with the colloidal particles (12) preferably transports holes and is made of a material selected from the group consisting of PDOT or TPD.

9. An electroluminescent arrangement according to claim 5, characterized in that the transportation layer (11) with the colloidal particles (12) preferably transports electrons.

10. An electroluminescent arrangement according to claim 5, characterized in that the light emitting layer (13) is a polymer and/or a solution processed organic material.

11. An electroluminescent arrangement according to claim 5, characterized in that the light emitting layer (13) is made of a vacuum deposited organic material.

12. Use of an electroluminescent arrangement according to claim 5 as an active matrix display, a passive matrix display or a light source either for monochrome or for full color application.
